(19) United States
(12) Patent Application Publication
(10) Pub. No.: US 2014/0087677 A1
(43) Pub. Date: Mar. 27, 2014

(54) APPARATUS AND METHOD FOR CONTROLLING POWER IN TRANSMITTING DEVICE

(71) Applicant: Samsung Electronics Co. Ltd., Suwon-si (KR)

(72) Inventors: Seong-Wook SONG, Gwacheon-si (KR); Joo-Han KIM, Yongin-si (KR); Dong-Kyoon CHO, Suwon-si (KR)

(73) Assignee: Samsung Electronics Co. Ltd., Suwon-si (KR)

(21) Appl. No.: 14/038,079

(22) Filed: Sep. 26, 2013

(30) Foreign Application Priority Data
Sep. 26, 2012 (KR) 10-2012-0107400

(51) Int. Cl. H03G 3/00

(52) U.S. Cl. CPC H03G 3/004
USPC 455/127.2; 330/127

(57) ABSTRACT

A power control method for controlling a bias voltage of a power amplifier in a transmitting device having the power amplifier is provided. The power control method includes estimating a Peak-to-Average Power Ratio (PAPR) during signal transmission using basis information that is configured for communication in the transmitting device and controlling a bias voltage of the power amplifier based on the estimated PAPR.

### CROSS-REFERENCE TO RELATED APPLICATION(S)

This application claims the benefit under 35 U.S.C. §119(a) of a Korean patent application filed on Sep. 26, 2012 in the Korean Intellectual Property Office and assigned Serial No. 10-2012-0107400, the entire disclosure of which is hereby incorporated by reference.

### TECHNICAL FIELD

The present disclosure relates to power amplification in a wireless communication system. More particularly, the present disclosure relates to an apparatus and method for controlling a bias voltage of a Power Amplifier (PA) in a transmitting device for a wireless communication system.

### BACKGROUND

Typically, a transmitting device in a wireless communication system includes a power amplifier. The power amplifier may serve to transmit signals at desired strength. A transmitting device may be provided in a wireless terminal and also in a base station.

Power consumption of the power amplifier can occupy a large portion of the total power consumption of the transmitting device. In other words, the power consumption of the transmitting device may be directly affected by the power consumption of the power amplifier. Therefore, power control technology for the power amplifier may be an important component of the transmitting device.

Furthermore, the linearity of the power amplifier is an important factor for achieving an optimal Error Vector Magnitude (EVM) or Adjacent Channel Leakage Ratio (ACLR) in the wireless communication system. This is because the nonlinearity of the power amplifier may distort the output signals, causing degradation of communication performance.

In some such cases, a linear Radio Frequency (RF) power amplifier may use the class-A structure to match the linearity level. For example, a power amplifier equipped in a transmitting device may keep its linearity at a power level less than or equal to a compression point of 1 dB. In other words, the power amplifier equipped in the transmitting device may show its maximum efficiency at the 1 dB compression point.

However, it is difficult for the power amplifier to maintain linearity if the input-output voltage approaches the saturation region. For example, a power amplifier designed to maintain the linearity in a high input-output voltage region may unnecessarily consume power in a low input-output voltage region, causing a reduction in battery life of the transmitting device.

The above information is presented as background information only to assist with an understanding of the present disclosure. No determination has been made, and no assertion is made, as to whether any of the above might be applicable as prior art with regard to the present disclosure. Accordingly, there is a need for and improved apparatus and method for maintaining linearity of a power amplifier.

### SUMMARY

Aspects of the present disclosure are to address at least the above-mentioned problems and/or disadvantages and provide at least the advantages described below. Accordingly, an aspect of the present disclosure is to provide a power control apparatus and method for varying a bias voltage while maintaining the linearity of a power amplifier based on the input-output estimation of the power amplifier in a transmitting device for a wireless communication system.

Another aspect of the present disclosure is to provide an apparatus and method for controlling a bias voltage of a power amplifier by a Peak-to-Average Power Ratio (PAPR) estimated based on the communication situation in a transmitting device for a wireless communication system.

Another aspect of the present disclosure is to provide an apparatus and method for controlling a bias voltage of a power amplifier based on the transmission mode in a transmitting device for a wireless communication system.

Another aspect of the present disclosure is to provide an apparatus and method for controlling a bias voltage of a power amplifier by estimating a PAPR based on at least one of a transmission mode for signal transmission, a type of physical channel or combination of physical channels and a transfer rate in a transmitting device for a wireless communication system.

In accordance with an aspect of the present disclosure, a power control method for controlling a bias voltage of a power amplifier in a transmitting device having the power amplifier is provided. The power control method includes estimating a PAPR during signal transmission using basis information that is configured for communication in the transmitting device and controlling a bias voltage of the power amplifier based on the estimated PAPR.

In accordance with another aspect of the present disclosure, a power control apparatus for controlling a bias voltage of a power amplifier in a transmitting device having the power amplifier is provided. The power control apparatus includes a PAPR estimator configured to estimate a PAPR during signal transmission using basis information that is configured for communication in the transmitting device and a power adjuster for controlling a bias voltage of the power amplifier based on the PAPR estimated by the PAPR estimator.

In accordance with another aspect of the present disclosure, a power control method for controlling a bias voltage of a power amplifier in a transmitting device having the power amplifier is provided. The power control method includes controlling a bias voltage of the power amplifier using basis information that is configured for communication in the transmitting device so that a PAPR in the transmitting device may be maintained at an estimated PAPR.

In accordance with yet another aspect of the present disclosure, a transmitting device that includes a power amplifier for amplifying an input signal with a bias voltage and a power control apparatus for controlling a bias voltage of the power amplifier is provided. The power amplifier uses basis information that is configured for communication in the transmitting device so that a PAPR in the transmitting device may be maintained at an estimated PAPR.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 illustrates an example of a structure for controlling power of a power amplifier equipped in a transmitting device for a wireless communication system according to an embodiment of the present disclosure;

FIG. 2 illustrates an example of a structure of a power controller, such as the power controller shown in FIG. 1, according to an embodiment of the present disclosure;

FIG. 3 illustrates an example of a structure of a power adjuster, such as the power adjuster shown in FIG. 2, according to an embodiment of the present disclosure;

FIG. 4 illustrates a control flow for adjusting a bias voltage of a power amplifier in a transmitting device for a wireless communication system according to an embodiment of the present disclosure;

FIG. 5 illustrates an example of a change in a collector current Ic (or Icc) due to a change in a bias voltage of a power amplifier according to an embodiment of the present disclosure; and

FIG. 6 illustrates an example of a change in input-output voltage of a power amplifier and in power consumption of the power amplifier due to a change in voltage applied to the power amplifier according to an embodiment of the present disclosure.

Throughout the drawings, like reference numerals will be understood to refer to like parts, components, and structures.

### DETAILED DESCRIPTION

The following description with reference to the accompanying drawings is provided to assist in a comprehensive understanding of various embodiments of the present disclosure as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the present disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the present disclosure is provided for illustration purpose only and not for the purpose of limiting the present disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

By the term “substantially” it is meant that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

In a below-described embodiment of the present disclosure, a description will be made of a manner to control a bias voltage of a power amplifier using basis information that a transmitting device considers for signal transmission.

For example, a transmitting device may collect basis information about a transmission mode, the number of Orthogonal Variable Spreading Factor (OVSF) codes and a combination of transmission channels. The transmitting device may estimate a Peak-to-Average Power Ratio (PAPR) of transmission data using the collected basis information, or find a PAPR using a look-up table in which a PAPR optimized for each situation is stored. The transmitting device may determine or check a bias voltage and Vcc, which are most suitable for the current situation, taking into account the PAPR estimated or found in the look-up table. The transmitting device may control its power amplifier based on the determined bias voltage and Vcc.

In an embodiment of the present disclosure, the basis information used to estimate a PAPR may include most of the information that the transmitting device takes into account to perform communication. For example, the basis information may include information about at least one of a communication scheme, a transmission mode, a type of physical channels, a combination of physical channels, and a data transfer rate.

The information about a communication scheme may be information indicating the communication scheme supported by the transmitting device. For example, the information about a communication scheme may be information for distinguishing communication schemes such as Code Division Multiple Access (CDMA) and Orthogonal Frequency Division Multiplexing (OFDM), or information for distinguishing a 2^{nd} generation scheme, a 3^{rd} generation scheme, a 4^{th} generation scheme, and the like. For example, the 2^{nd} generation scheme may be Global System for Mobile communication (GSM), the 3^{rd} generation scheme may be Wideband Code Division Multiple Access (WCDMA), and the 4^{th} generation scheme may be Long Term Evolution (LTE).

The information about a transmission mode may be information indicating the transmission mode served by the transmitting device. For example, the information about a transmission mode may include information for distinguishing a voice transmission mode, a data transmission mode, and the like. The transmission mode may be selectively used at the user's request.

The information about a type of physical channels and a combination of physical channels may be information about the type or combination of physical channels for carrying a signal depending on the communication scheme and/or transmission mode to be used by the transmitting device, or information about the combination of physical channels. For example, the type of physical channels may include Dedicated Physical Data Channel (DPDCH), Dedicated Physical Control Channel (DPCCH), High Speed DPCCH (HS-DPCCH), Enhanced Dedicated Channel (E-DCH) and the like. The combination of physical channels may correspond to a combination of at least two physical channels that may be used together.

The information about a data transfer rate may be used to define a transfer rate of the data that the transmitting device will transmit using the above-defined communication scheme, transmission mode, type of physical channels, and combination of physical channels. For example, the transfer rate may be the number of OVSF codes that a base station assigns to each user or terminal by scheduling.

In the below-described various embodiments of the present disclosure, implementations for controlling a bias voltage (or Vcc) of a power amplifier, optimized for a transmitting device, are presented.

The transmitting device may control a bias voltage (or Vcc) of the power amplifier based on a communication scheme to be used for signal transmission. Thus, if the transmitting device supports a variety of communication schemes, the transmitting device may adjust a bias voltage (or Vcc) of the power amplifier to an optimal value in accordance with the communication scheme in use.

For example, the transmitting device may control the power amplifier to use a different bias voltage when using WCDMA as the communication scheme than when using LTE as the communication scheme.

Even when the communication scheme includes CDMA, OFDM, Time Division Multiple Access (TDMA) and the like, the transmitting device may control the bias voltage (or Vcc) of the power amplifier in accordance with which communication scheme will be used.

Second, the transmitting device may control a bias voltage (or Vcc) of the power amplifier based on the transmission mode. For example, the transmission mode may be determined depending on the type of transmission signals. Thus, if the transmitting device supports a variety of transmission modes, the transmitting device may adjust a bias voltage (Vcc) of the power amplifier to an optimal value in accordance with the transmission mode in use.

For example, the transmitting device may control the power amplifier to use a different bias voltage when using a voice transmission mode as the transmission mode than when using a data transmission mode as the transmission mode.

The voice transmission mode requires lower operating power compared to the data transmission mode. Therefore, a higher PAPR may be estimated in the data transmission mode compared to the voice transmission mode, so the transmitting device may be configured to decrease a bias voltage (or Vcc) of the power amplifier in the voice transmission mode compared to the data transmission mode, thereby making it possible to prevent unnecessary power consumption from occurring in the voice transmission mode.

Third, the transmitting device may control a bias voltage (or Vcc) of the power amplifier based on the allocated channels. Thus, if a variety of channels are allocated to the transmitting device, the transmitting device may adjust a bias voltage (or Vcc) of the power amplifier to an optimal value in accordance with the type of the allocated channel or the combination of channels to be used at the same time.

An implementation provided as the transmitting device can select and use at least one of a variety of channels such as DPDCH, DPCCH, HS-DPCCH and E-DCH depending on the communication specifications and purposes. Typically, it is possible to predict that a PAPR will be changed in proportion to the number of channels that can be transmitted at the same time. In other words, as the number of channels that can be transmitted at the same time becomes larger, a higher PAPR may be predicted. By contrast, as the number of channels that can be transmitted at the same time becomes smaller, a lower PAPR may be predicted.

For example, the transmitting device may predict different PAPRs depending on the type of available channels and the combination of channels that can be transmitted at the same time. Thus, as the number of channels that can be transmitted at the same time is smaller, the transmitting device may decrease a bias voltage (or Vcc) of the power amplifier. As a result, the transmitting device may prevent the occurrence of unnecessary power consumption depending on the type of channels, the number of channels that can be transmitted at the same time, and/or the combination of the channels that can be transmitted at the same time. Further, the transmitting device may maintain the linearity of its power amplifier.

Fourth, the transmitting device may control a bias voltage (or Vcc) of the power amplifier based on an assigned data transfer rate. Thus, if the transmitting device is assigned a data transfer rate, the transmitting device may adjust a bias voltage (or Vcc) of the power amplifier to an optimal value in accordance with the assigned data transfer rate.

The base station may assign the data transfer rate to be used by the transmitting device, in accordance with communication situations such as the performance of the transmitting device, the amount of data to be transmitted, and the wireless communication environment. The transmitting device may transmit signals at the assigned data transfer rate. Therefore, the transmitting device may adjust a bias voltage (or Vcc) of the power amplifier to an optimal value based on the assigned data transfer rate.

The transmitting device supporting, for example, CDMA may be assigned a plurality of OVSF codes from the base station depending on the amount of data to transmit. Since a PAPR typically varies depending on the number of assigned OVSF codes, the transmitting device may predict a PAPR based on the number of assigned OVSF codes.

In other embodiments, if the transmitting device is assigned four OVSF codes, the number of which corresponds to the maximum number of OVSF codes assignable for High Speed Uplink Packet Access (HSUPA), the transmitting device may predict the highest PAPR. By contrast, if the transmitting device is assigned one OVSF code, the number of which corresponds to the minimum number of OVSF codes assignable for HSUPA, the transmitting device may predict the lowest PAPR.

The transmitting device may control a bias voltage (or Vcc) of the power amplifier in proportion to the number of OVSF codes that are assigned to the transmitting device itself for HSUPA. For example, the transmitting device may decrease a bias voltage (or Vcc) of the power amplifier as the number of assigned OVSF codes is smaller, and may increase a bias voltage (or Vcc) of the power amplifier as the number of assigned OVSF codes is larger. As a result, the transmitting device may prevent unnecessary power consumption from occurring in the power amplifier depending on the number of OVSF codes assigned to the transmitting device itself.

Various embodiments of the present disclosure are now described with reference to the accompanying drawings. Throughout the drawings, like reference numerals will be understood to refer to like parts, components, and structures. In addition, descriptions of well-known functions and constructions may be omitted for clarity and conciseness.

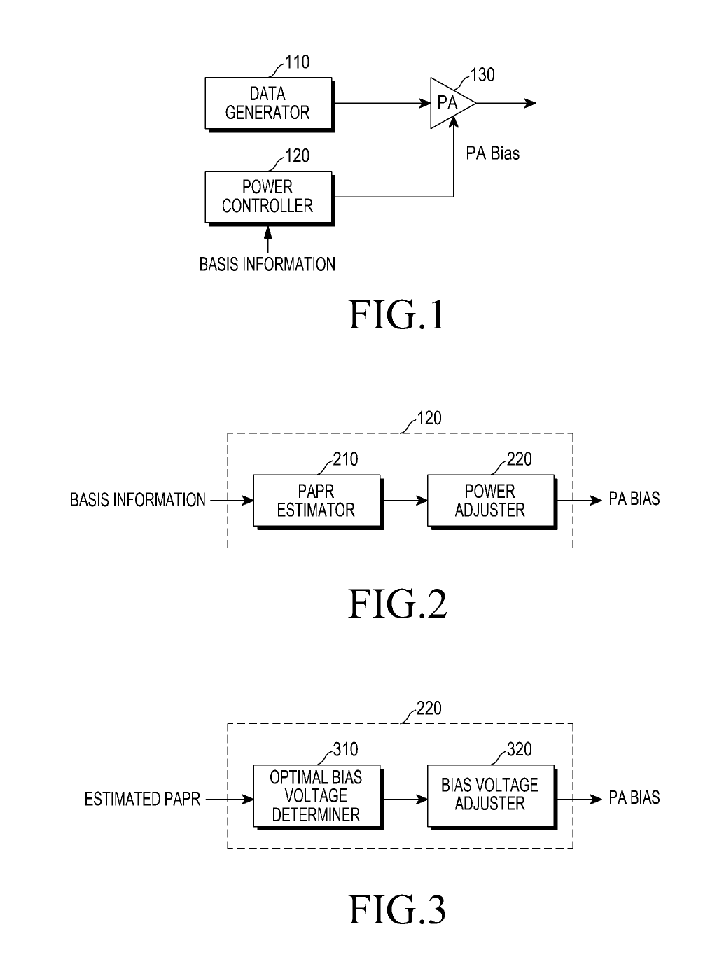

FIG. 1 illustrates an example of a structure for controlling power of a power amplifier equipped in a transmitting device according to an embodiment of the present disclosure.

Referring to FIG. 1, a data generator 110 may generate transmission data depending on basis information. A power controller 120 may collect basis information for data transmission, and control a bias voltage (PA Bias) of a power amplifier 130 using the collected basis information. The above examples may be applied in the same way to the operation in which the power controller 120 controls a bias voltage of the power amplifier 130 using the collected basis information. The power amplifier 130 may amplify power of the data generated by the data generator 110 with the bias voltage provided from the power controller 120.

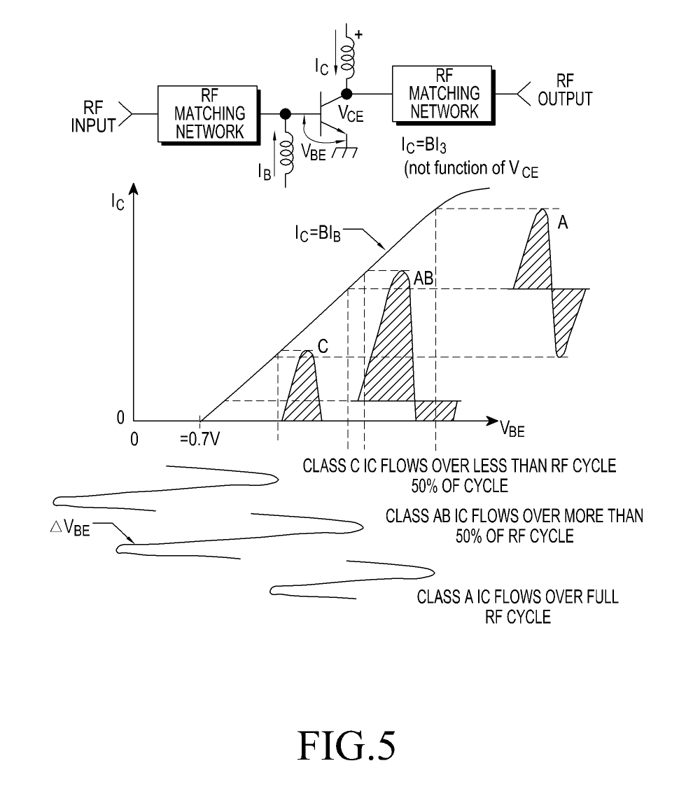

FIG. 5 illustrates an example of a change in a collector current Ic (or Icc) due to a change in bias voltage in a power amplifier according to an embodiment of the present disclosure.

Referring to FIG. 5, if a bias voltage is excessively lower than an input-output voltage, the output signal may be distorted due to the cut-off By contrast, if a bias voltage is excessively higher than an input-output voltage, the output signal may be distorted due to the saturation.

Therefore, it can be appreciated that if the required input-output voltage is low, the bias voltage may be decreased within the range where the linearity is maintained. In other words, if the bias voltage is decreased, a value of Ic decreases, leading to a reduction in the power consumption (P_{dc}=Vcc*Icc) in the power amplifier.

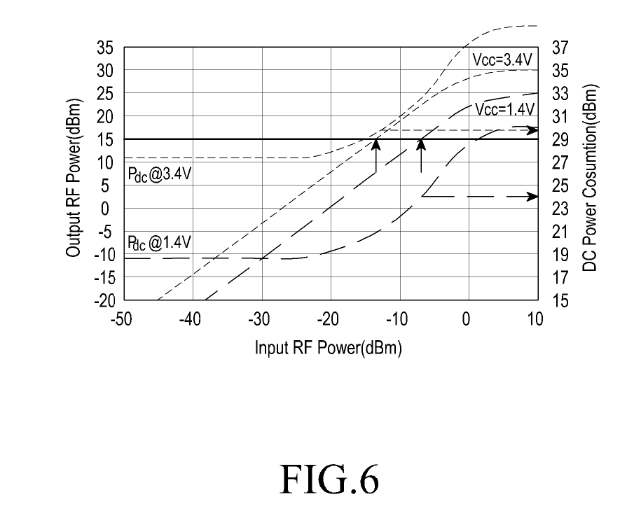

FIG. 6 illustrates an example of a change in input-output voltage of a power amplifier and in power consumption (P_{dc}=Vcc*Icc) of the power amplifier due to a change in voltage Vcc applied to the power amplifier according to an embodiment of the present disclosure.

Referring to FIG. 6, if 3.4V is applied as Vcc, power consumption P_{dc} for obtaining an output voltage 15 dBm of the power amplifier is 30 dBm. However, if Vcc is decreased to 1.4V, power consumption P_{dc} for obtaining an output voltage 15 dBm of the power amplifier is decreased to 24 dBm. In other words, if Vcc is decreased from 3.4V to 1.4V, the power consumption P_{dc} for obtaining an output voltage of 15 dBm is reduced by 6 dBm.

Thus if the output voltage of the power amplifier is 15 dBm, the linearity of the power amplifier may be maintained even though Vcc is decreased to 1.4V. Therefore, if the input-output voltage of the power amplifier is low, the power consumed in the power amplifier may be reduced by decreasing a value of Vcc.

Further, if Vcc is decreased, the 1 dB compression point is also decreased, making it possible to prevent a decrease in the efficiency of amplifier from occurring due to the bias back-off. For example, if Vcc is 3.4V, the compression point is 28 dBm. However, if Vcc is decreased to 1.4V, the compression point is decreased to 20 dBm. In other words, if Vcc is decreased from 3.4V to 1.4V, the compression point may be reduced by 8 dBm.

FIG. 2 illustrates an example of a structure of a power controller, such as the power controller shown in FIG. 1, according to an embodiment of the present disclosure.

Referring to FIG. 2, a PAPR estimator 210 may estimate a PAPR during signal transmission, using the basis information set in the transmitting device. The PAPR estimator 210 may estimate a PAPR for preventing unnecessary power consumption from occurring in the power amplifier. For example, the PAPR estimator 210 may estimate a PAPR using an equation defining a PAPR, or a predefined look-up table.

If the PAPR estimator 210 estimates a PAPR using the equation, the PAPR estimator 210 may estimate a PAPR using power of the output signal of the transmitting device, because the PAPR may be defined by a ratio

$$\frac{{x}_{peak}^{2}}{E [ {x}^{2} ]}$$

of the maximum value xₚₑₐₖ² of the output signal to average power E[x²] of the output signal.

If the PAPR estimator 210 estimates a PAPR using the look-up table, the PAPR estimator 210 may configure a look-up table. For example, the look-up table may be predefined with the optimal PAPR which can be estimated based on each of basis information.

The look-up table may be stored in an internal recording medium of the PAPR estimator 210, or in an external recording medium. The PAPR estimator 210 may collect basis information, and search the look-up table for basis information matching (or equivalently identical to) the collected basis information.

Upon detecting the collected basis information from the look-up table, the PAPR estimator 210 may obtain the optimal PAPR that is set to correspond to the basis information detected from the look-up table. The optimal PAPR may be estimated as a PAPR that the transmitting device will take into account to adjust a bias voltage (or Vcc) of the power amplifier. The PAPR estimator 210 may provide the estimated PAPR to a power adjuster 220. The power adjuster 220 may control a bias voltage of the power amplifier 130 based on the PAPR estimated by the PAPR estimator 210.

More specifically, the power adjuster 220 may select the optimal bias voltage (or Vcc) of the power amplifier 130 in the current communication environment based on the PAPR estimated by the PAPR estimator 210. The power adjuster 220 may adjust the bias voltage of the power amplifier 130 based on the selected optimal bias voltage (or Vcc). For example, the power adjuster 220 may adjust the bias voltage of the power amplifier 130 to the selected optimal bias voltage (or Vcc).

A method for the power adjuster 220 controlling the power amplifier 130 based on the selected optimal bias voltage has been described with reference to FIGS. 5 and 6, so an additional description thereof is omitted.

FIG. 3 illustrates an example of a structure of a power adjuster, such as the power adjuster shown in FIG. 2, according to an embodiment of the present disclosure.

Referring to FIG. 3, an optimal bias voltage determiner 310 may receive, as its input, the PAPR estimated by the PAPR estimator 210, and determine an optimal bias voltage (or Vcc) of the power amplifier 130 in the current communication environment which is predicted based on the estimated PAPR.

A bias voltage adjuster 320 may adjust a bias voltage of the power amplifier 130 to the optimal bias voltage determined by the optimal bias voltage determiner 310. As described, power consumption may be reduced by adjusting a bias voltage of the power amplifier 130.

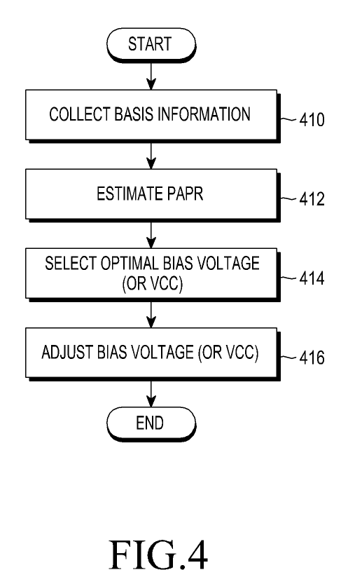

FIG. 4 illustrates a control flow for adjusting a bias voltage of a power amplifier in a transmitting device according to an embodiment of the present disclosure.

Referring to FIG. 4, the transmitting device may collect basis information in operation 410. The transmitting device may collect, as basis information, information about at least one of a communication scheme, a transmission mode, a type of physical channel, a combination of physical channels, and a data transfer rate. The information that can be collected as the basis information has been described above, so a detailed description thereof is omitted. The transmitting device may define the basis information based on various combinations of the information described above.

For example, the transmitting device may collect basis information from a hardware or software block that generates transmission data, or may collect basis information from the external network or the user. Furthermore, for each type of basis information collected, the collection path may be independent. In other words, information about the communication scheme and/or the transmission mode may be collected from a hardware or software block that generates transmission data, and information about the type of physical channels, the combination of physical channels, and/or the data transfer rate may be collected from a receiving device or a user over the external network.

After completion of collecting the basis information, the transmitting device may estimate a PAPR during signal transmission using the collected basis information in operation 412. As for the estimation of a PAPR, the PAPR may be estimated using an equation defining a PAPR, or a predefined look-up table.

As for the estimation of a PAPR using the equation, the PAPR may be defined by a ratio

$$\frac{{x}_{peak}^{2}}{E [ {x}^{2} ]}$$

of the maximum value xₚₑₐₖ² of the output signal to average power E[x²] of the output signal. This may be expressed as an equation of

$$PAPR = \frac{{x}_{peak}^{2}}{E [ {x}^{2} ]} .$$

As can be appreciated from this equation, the transmitting device may estimate a PAPR only with the power of its output signal based on the collected basis information.

In the look-up table for the PAPR estimation may be defined an optimal PAPR that can be estimated based on each of the basis information. After collecting the basis information, the transmitting device determines basis information matching the basis information collected from the look-up table. The transmitting device may determine an optimal PAPR that is set in the look-up table to correspond to the determined basis information. The determined optimal PAPR will be taken into account to adjust a bias voltage (or Vcc) of the power amplifier.

In operation 414, the transmitting device may select an optimal bias voltage (or Vcc) of the power amplifier in the current communication environment based on the optimal PAPR (for example, a PAPR to be taken into account to adjust a bias voltage). For example, the optimal bias voltage (or Vcc) may refer to a bias voltage (or Vcc) that is set to prevent unnecessary power consumption from occurring in the power amplifier.

After selecting the optimal bias voltage (or Vcc), the transmitting device may adjust a bias voltage of the power amplifier to the selected optimal bias voltage (or Vcc) in operation 416.

The power amplifier equipped in the transmitting device may amplify power of the transmission signal with the adjusted bias voltage.

It can be appreciated that the above-described embodiments of the present disclosure may be implemented in the form of hardware, software, or a combination thereof. The software may be stored in volatile or non-volatile storages (for example, erasable or re-writable Read Only Memory (ROM)), memories (for example, Random Access Memory (RAM), memory chip, memory device, or memory Integrated Circuit (IC)), or optically/magnetically writable machine (for example, computer)-readable storage media (for example, Compact Disk (CD), Digital Versatile Disk (DVD), magnetic disk, or magnetic tape).

The power control apparatus and method proposed by the present disclosure may be implemented by a computer or a mobile terminal, which includes a controller and a memory. The memory may be an example of machine-readable storage media suitable to store a program(s) including instructions for implementing the embodiments of the present disclosure. Therefore, the present disclosure may include a program including codes for implementing the apparatus and/or method as defined by the appended claims, and a machine (or computer)-readable storage medium storing the program. This program may be electronically transmitted through any medium such as communication signals which are transmitted via wire/wireless connections. The present disclosure may include equivalents thereto.

The power control apparatus and method may receive and store the program from a program server to which it is connected by wires or wirelessly. The program server may include a memory for storing the program including instructions for implementing the embodiments of the present disclosure, and information needed for the power control method, a communication unit for performing wired/wireless communication with the power control apparatus, and a controller for transmitting the program to the power control apparatus automatically or at a request of the power control apparatus.

As is apparent from the foregoing description, in embodiments of the present disclosure, a bias voltage of a power amplifier equipped in a transmitting device may be varied taking into account a transmission mode, a transfer rate, a channel type and the like, thereby making it possible to control the power consumption by the power amplifier according to the communication situation. As a result, the power consumption of the transmitting device may be reduced.

In addition, in embodiments of the present disclosure, there is no need to calculate a PAPR in real time in order to control a bias voltage of a power amplifier, so PAPR calculation-related operations such as computation, control and buffering may be omitted, thereby contributing to a reduction in the amount of signal processing by the transmitting device, and to the simplification of hardware.

While the present disclosure has been shown and described with reference to various embodiments thereof, it will be understood by those skilled in the art that various changes in form and details may be made therein without departing from the spirit and scope of the present disclosure as defined by the appended claims and their equivalents.

What is claimed is:

1. A power control method for controlling a bias voltage of a power amplifier in a transmitting device having the power amplifier, the power control method comprising:
estimating a Peak-to-Average Power Ratio (PAPR) during signal transmission using basis information that is configured for communication in the transmitting device; and
controlling a bias voltage of the power amplifier based on the estimated PAPR.

2. The power control method of claim 1, wherein the basis information includes information about a communication scheme supported by the transmitting device.

3. The power control method of claim 1, wherein the basis information includes information about a transmission mode for transmitting a signal in the transmitting device.

4. The power control method of claim 1, wherein the basis information includes information about a type of physical channel or a combination of physical channels for transmitting a signal in the transmitting device.

5. The power control method of claim 1, wherein the basis information includes information about a data transfer rate assigned to transmit a signal in the transmitting device.

6. The power control method of claim 1, wherein the basis information includes at least one of information about a communication scheme supported by the transmitting device, information about a transmission mode for transmitting a signal in the transmitting device, information about a type of physical channel or a combination of physical channels for transmitting a signal in the transmitting device, and information about a data transfer rate assigned to transmit a signal in the transmitting device.

7. The power control method of claim 1, wherein the estimating of the PAPR comprises:
configuring a look-up table for specifying a PAPR that can be estimated based on each of basis information which can be configured for communication in the transmitting device; and
obtaining a PAPR, which is specified in the look-up estimated based on basis information which is configured for communication in the transmitting device.

8. The power control method of claim 1, wherein the controlling of the bias voltage comprises calculating output power of the power amplifier, and controlling a bias voltage of the power amplifier in accordance with the estimated PAPR and the calculated output power.

9. A power control apparatus for controlling a bias voltage of a power amplifier in a transmitting device having the power amplifier, the power control apparatus comprising:
a Peak-to-Average Power Ratio (PAPR) estimator configured to estimate a PAPR during signal transmission using basis information that is configured for communication in the transmitting device; and
a power adjuster for controlling a bias voltage of the power amplifier based on the PAPR estimated by the PAPR estimator.

10. The power control apparatus of claim 9, wherein the basis information includes information about a communication scheme supported by the transmitting device.

11. The power control apparatus of claim 9, wherein the basis information includes information about a transmission mode for transmitting a signal in the transmitting device.

12. The power control apparatus of claim 9, wherein the basis information includes information about a type of physical channel or a combination of physical channels for transmitting a signal in the transmitting device.

13. The power control apparatus of claim 9, wherein the basis information includes information about a data transfer rate assigned to transmit a signal in the transmitting device.

14. The power control apparatus of claim 9, wherein the basis information includes at least one of information about a communication scheme supported by the transmitting device, information about a transmission mode for transmitting a signal in the transmitting device, information about a type of physical channel or a combination of physical channels for transmitting a signal in the transmitting device, and information about a data transfer rate assigned to transmit a signal in the transmitting device.

15. The power control apparatus of claim 9, wherein the PAPR estimator configures a look-up table for specifying a PAPR that can be estimated based on each of basis information which can be configured for communication in the transmitting device, and obtains a PAPR from the look-up table to be able to be estimated based on basis information which is configured for communication in the transmitting device.

16. The power control apparatus of claim 9, wherein the power adjuster calculates output power of the power amplifier, and controls a bias voltage of the power amplifier in accordance with the estimated PAPR and the calculated output power.

17. A power control method for controlling a bias voltage of a power amplifier in a transmitting device having the power amplifier, the power control method comprising:
controlling a bias voltage of the power amplifier using basis information that is configured for communication in the transmitting device so that a Peak-to-Average Power Ratio (PAPR) in the transmitting device may be maintained at an estimated PAPR.

18. The power control method of claim 17, wherein the basis information includes information about a communication scheme supported by the transmitting device.

19. The power control method of claim 17, wherein the basis information includes information about a transmission mode for transmitting a signal in the transmitting device.

20. The power control method of claim 17, wherein the basis information includes information about at least one of a type of physical channel or a combination of physical channels assigned to transmit a signal in the transmitting device, and a data transfer rate assigned to transmit a signal in the transmitting device.

21. A transmitting device comprising:
a power amplifier for amplifying an input signal with a bias voltage; and
a power control apparatus for controlling a bias voltage of the power amplifier using basis information configured for communication in the transmitting device so that a Peak-to-Average Power Ratio (PAPR) in the transmitting device may be maintained at an estimated PAPR.

22. The transmitting device of claim 21, wherein the basis information includes information about a communication scheme supported by the transmitting device.

23. The transmitting device of claim 21, wherein the basis information includes information about a transmission mode for transmitting a signal in the transmitting device.

24. The transmitting device of claim 21, wherein the basis information includes information about at least one of a type of physical channel or a combination of physical channels assigned to transmit a signal in the transmitting device, and a data transfer rate assigned to transmit a signal in the transmitting device.
